(19) United States
(12) Patent Application Publication
(10) Pub. No.: US 2024/0431039 A1
(43) Pub. Date: Dec. 26, 2024

(54) INFORMATION PROCESSING DEVICE

(71) Applicant: NIDEC INSTRUMENTS CORPORATION, Nagano (JP)

(72) Inventors: Yuji FUJIMORI, Nagano (JP); Keiji OHTA, Nagano (JP)

(21) Appl. No.: 18/747,449

(22) Filed: Jun. 19, 2024

(30) Foreign Application Priority Data
Jun. 20, 2023 (JP) 2023-101040

(51) Int. Cl. H05K 5/00; H01Q 1/20

(52) U.S. Cl. CPC H05K 5/0008; H01Q 1/20; H05K 5/0013

(57) ABSTRACT

An information processing device for performing communication with a medium in a non-contact manner includes a case having a first face part to which a medium is brought close, an antenna board which faces the first face part and includes an antenna for communicating with the medium, and a metal screw which is fastened to a screw hole formed in the case to fix the antenna board to the case. In an arrangement direction in which the first face part and the antenna board are arranged, when a side where the first face part is located is a first side, and a side where the antenna board is located is a second side, the screw is located on the second side with respect to the antenna board and, when viewed in a direction perpendicular to the arrangement direction, the screw is not overlapped with the antenna board.

### CROSS REFERENCE TO RELATED APPLICATION

The present invention claims priority under 35 U.S.C. § 119 to Japanese Application No. 2023-101040 filed Jun. 20, 2023, the entire content of which is incorporated herein by reference.

### TECHNICAL FIELD

At least an embodiment of the present invention may relate to an information processing device which performs communication by electromagnetic induction with a medium such as a smart phone having a short-range wireless communication (NFC; Near Field Communication) function and a non-contact type IC card.

### BACKGROUND

A non-contact type information processing device which performs reading and writing of data in a non-contact manner on a medium such as a non-contact type IC card is described in Japanese Patent Laid-Open No. 2021-057725 (Patent Literature 1). The information processing device described in Patent Literature 1 includes a bezel and a loop antenna which is disposed in an inside of the bezel and is used for communication with a medium. The information processing device performs reading and writing of data on a medium in a non-contact manner by making the medium lightly touch or close to a front face of the bezel.

The loop antenna is mounted on one face of an antenna board. The antenna board is fixed to the bezel by a metal screw at a position facing a front face of the bezel in an inside of the bezel. The metal screw is penetrated through the antenna board. Therefore, when viewed in a direction perpendicular to an arrangement direction of the front face of the bezel and the antenna board, a part of the metal screw is located between a medium and the antenna. In a case that a part of the screw is located between a medium and the antenna, when the information processing device is used, the metal screw may affect communication between the medium and the antenna.

### SUMMARY

In view of the problem described above, at least an embodiment of the present invention may advantageously provide an information processing device which is capable of reducing influence of a metal screw on communication between a medium and an antenna even when an antenna board is fixed to a case by the metal screw.

According to at least an embodiment of the present invention, there may be provided an information processing device for performing communication with a medium in a non-contact manner which includes a case provided with a first face part to which a medium is brought close, an antenna board which faces the first face part in an inside of the case and includes an antenna for communicating with the medium, and a screw made of metal which is fastened to a screw hole formed in the case to fix the antenna board to the case. In an arrangement direction in which the first face part and the antenna board are arranged, when a side where the first face part is located is referred to as a first side, and a side where the antenna board is located is referred to as a second side, the screw is located on the second side with respect to the antenna board and, when viewed in a direction perpendicular to the arrangement direction, the screw is not overlapped with the antenna board.

According to this embodiment, the screw is located on the second side with respect to the antenna board and, when viewed in a direction perpendicular to the arrangement direction, the screw is not overlapped with the antenna board. As a result, influence of the screw on communication between a medium and the antenna can be reduced.

In this embodiment, it is preferable that the information processing device further includes a spacer which is disposed between the antenna board and a head part of the screw in the arrangement direction, the case is provided with a support part which supports the antenna board in the arrangement direction and a protruded part which is formed with the screw hole and is protruded from the first face part to the second side, the antenna board is provided with a hole part into which the protruded part is inserted, the spacer is formed in a tube shape into which the protruded part is inserted and presses the antenna board to the support part by a fastening force of the screw when the screw is fastened to the screw hole. According to this structure, even when the screw is located on the second side with respect to the antenna board, the screw is capable of fixing the antenna board to the case by using the spacer.

In this embodiment, it is preferable that the information processing device further includes a control board for controlling the antenna board which is disposed at an end part on the second side of the spacer, and the screw is fastened to the screw hole through the control board. According to this structure, the antenna board and the control board can be fixed to the case by one screw.

In this embodiment, it is preferable that the case includes a first case provided with the first face part and a second case which is attached to the first case from the second side and is provided with a second face part provided on the second side, and the screw is fastened to the screw hole through the second face part from the second side with respect to the second face part. According to this structure, the antenna board, the control board and the second case can be fixed to the first case by one screw.

In this embodiment, it is preferable that the antenna is provided on a face on the first side of the antenna board. According to this structure, communication sensibility between a medium and the antenna can be improved.

### Effects of the Invention

According to the embodiment of the present invention, a metal screw for fixing an antenna board is not located between a medium and an antenna and thus, influence of the metal screw on communication between the medium and the antenna can be reduced.

Other features and advantages of the invention will be apparent from the following detailed description, taken in conjunction with the accompanying drawings that illustrate, by way of example, various features of embodiments of the invention.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a perspective view showing an information processing device in accordance with a first embodiment of the present invention which is viewed from one side.

FIG. 2 is a perspective view showing the information processing device which is viewed from the other side.

FIG. 3 is an exploded perspective view showing the information processing device.

FIG. 4 is the “A-A” cross-sectional view showing the information processing device in FIG. 1.

FIG. 5 is a schematic view showing an antenna board.

FIG. 6 is a cross-sectional view showing an information processing device in accordance with a first modified embodiment of the present invention.

FIG. 7 is a cross-sectional view showing an information processing device in accordance with a second modified embodiment of the present invention.

### DETAILED DESCRIPTION

Embodiments of an information processing device to which the present invention is applied will be described below with reference to the accompanying drawings.

### First Embodiment

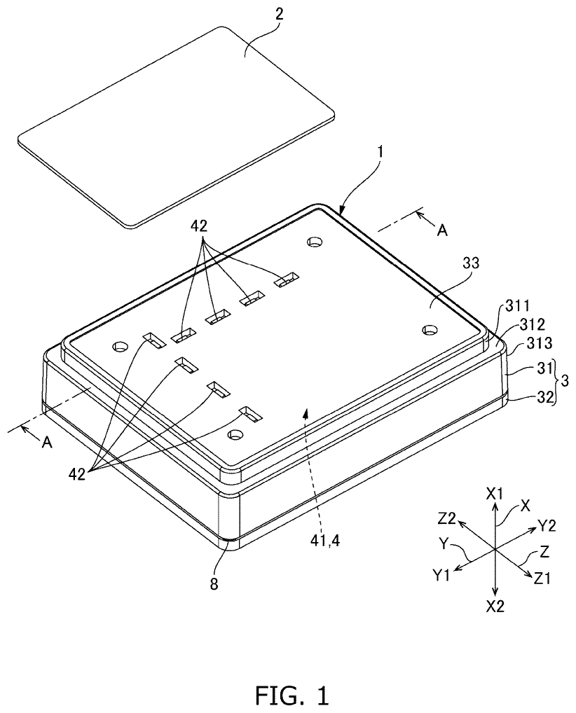

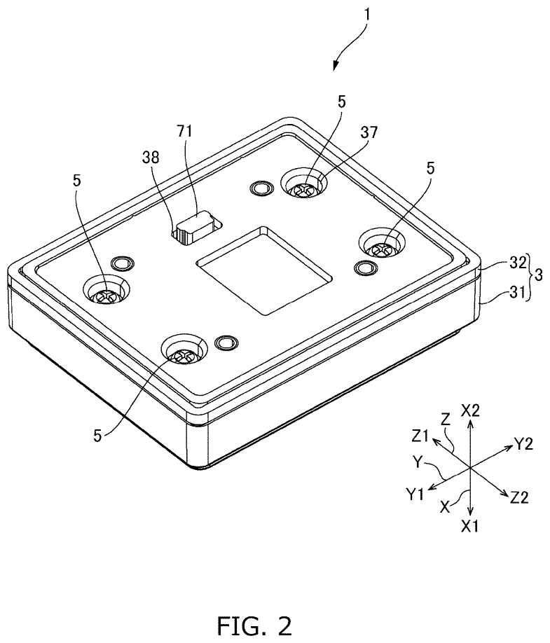

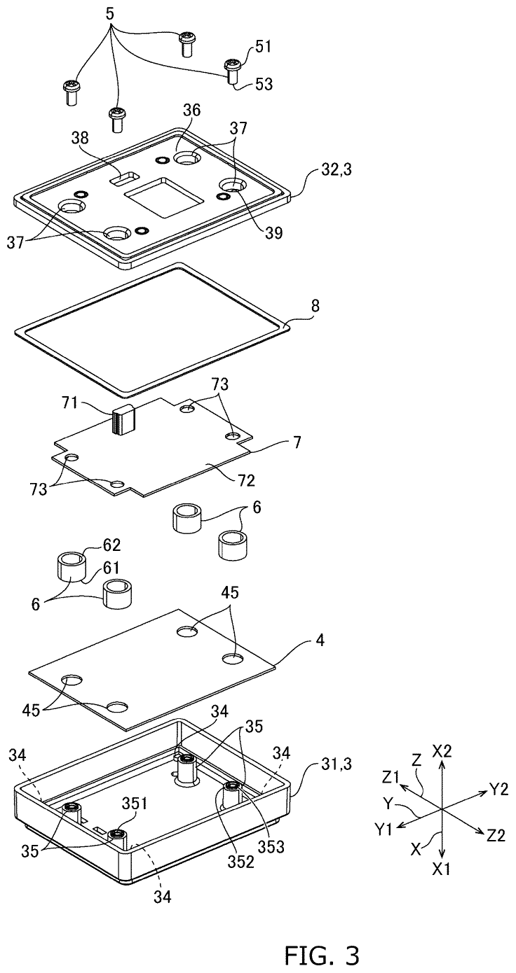

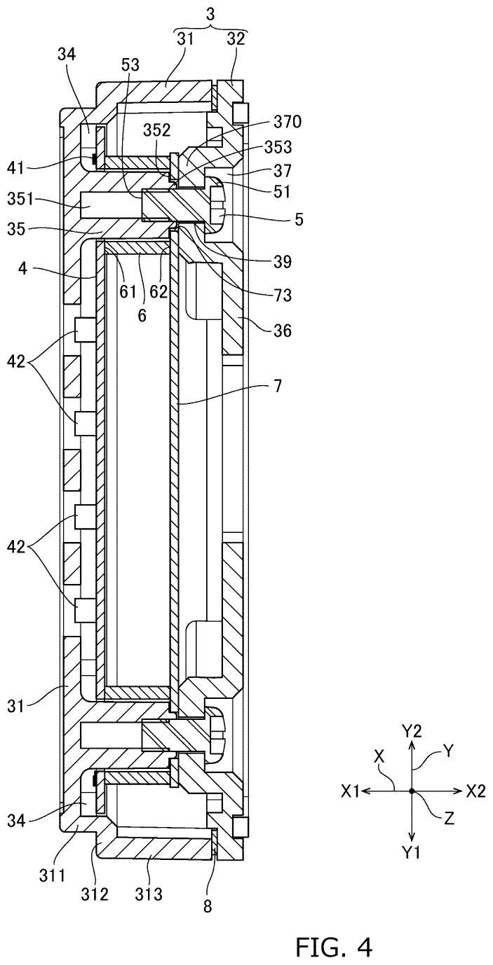

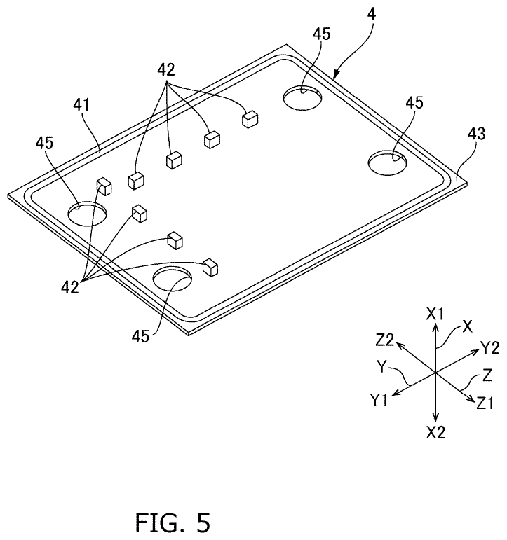

FIG. 1 is a perspective view showing an information processing device in accordance with a first embodiment of the present invention which is viewed from one side. FIG. 2 is a perspective view showing the information processing device which is viewed from the other side. FIG. 3 is an exploded perspective view showing the information processing device. FIG. 4 is the “A-A” cross-sectional view showing the information processing device in FIG. 1. FIG. 5 is a schematic view showing an antenna board.

An information processing device 1 in this embodiment is a device which is structured to perform communication with a medium 2 such as a smart phone having a short-range wireless communication (NFC; Near Field Communication) function and a non-contact type IC card and perform reading and writing of data on the medium 2. As shown in FIGS. 1 through 4, the information processing device 1 includes a case 3 provided with a first face part 33 to which a medium 2 is brought close, an antenna board 4 which faces the first face part 33 in an inside of the case 3, screws 5, spacers 6 which are disposed between the antenna board 4 and head parts 51 of the screws 5, and a control board 7 which controls the antenna board 4. In the information processing device 1, reading and writing of data are performed on the medium 2 by touching the medium 2 to the first face part 33 or by bringing the medium 2 close to the first face part 33.

In the following descriptions, three directions perpendicular to each other are defined as an “X” direction, a “Y” direction and a “Z” direction. The “X” direction is an arrangement direction in which the first face part 33 and the antenna board 4 are arranged. In the “X” direction, a side where the first face part 33 is located is referred to as an “X1” side (first side), and a side where the antenna board 4 is located is referred to as an “X2” side (second side). In the “Y” direction, one side is referred to as a “Y1” side, and the other side is referred to as a “Y2” side. One side in the “Z” direction is referred to as a “Z1” side, and the other side is referred to as a “Z2” side.

### (Case)

The case 3 is made of resin. When the case 3 is viewed in the “X” direction, the case 3 is formed in a quadrangular shape. The case 3 includes a first case 31 provided with the first face part 33 and a second case 32 which is attached to the first case 31 from the “X2” side. As shown in FIGS. 3 and 4, the first case 31 is provided with support parts 34 which support the antenna board 4 in the “X” direction, and protruded parts 35 which are protruded from the first face part 33 to the “X2” side.

The support part 34 is provided at four corners of a face on the “X2” side of the first face part 33. Four support parts 34 are contacted with the antenna board 4 and support the antenna board 4. The protruded part 35 is formed in a cylindrical tube shape. A center part of the protruded part 35 is formed with a screw hole 351.

As shown in FIGS. 1 and 4, the first case 31 is provided with a first side face part 311, which is protruded from an outer peripheral edge of the first face part 33 toward the “X2” side, a flat face part 312 enlarged from an end part of the first side face part 311, and a second side face part 313 which is protruded from an outer peripheral edge of the flat face part 312 toward the “X2” side. As shown in FIGS. 3 and 4, an end part on the “X2” side of the second side face part 313 is contacted with the second case 32 through a frame-shaped seal member 8. The seal member 8 is an elastic member and is made of rubber, silicone or the like.

As shown in FIGS. 3 and 4, the second case 32 is provided with a second face part 36 on the “X2” side. The second face part 36 is provided with recessed parts 37 which accommodate head parts 51 of the screws 5. The recessed part 37 is recessed to the “X1” side. A bottom face part 370 of the recessed part 37 is provided with a hole part 39 into which the screw 5 is inserted. The second case 32 is fixed to the first case 31 by the screws 5.

### (Antenna Board)

As shown in FIG. 5, the antenna board 4 is formed in a flat plate shape. The antenna board 4 includes a loop-shaped antenna 41 and eight LED elements 42 on its face 43 on the “X1” side. The antenna 41 is a coil antenna and communicates with a medium 2. The antenna 41 is disposed in the vicinity of an outer peripheral portion of the face 43 on the “X1” side. The LED elements 42 are disposed on an inner side with respect to the antenna 41. In accordance with an embodiment of the present invention, the number of the LED elements 42 is not limited to eight. The LED element 42 emits a light by output power from the control board 7. More specifically, in a case that a medium 2 is touched or brought close to the first face part 33 by a user, when the antenna 41 and the medium 2 are set in a distance capable of communicating with each other, the LED elements 42 emit lights to notify the user that the information processing device 1 is performing processing of reading and writing of data on the medium 2. On the other hand, when the antenna 41 and the medium 2 are not set in a distance capable of communicating with each other, the LED elements 42 do not emit lights to notify the user that the information processing device 1 does not perform processing on the medium 2.

As shown in FIGS. 3 through 5, the antenna board 4 is provided with circular hole parts 45 into which the protruded parts 35 are inserted. The hole parts 45 are disposed on an inner side with respect to the antenna 41. As shown in FIG. 4, the antenna board 4 is abutted with the support parts 34 in a state that the protruded parts 35 are inserted into the hole parts 45.

### (Spacer)

As shown in FIGS. 3 and 4, the spacer 6 is made of resin. The spacer 6 is formed in a tube shape into which the protruded part 35 is inserted. The spacer 6 is located between the antenna board 4 and the control board 7. In a state that the spacer 6 is inserted to the protruded part 35, an end part 61 on the “X1” side of the spacer 6 is abutted with the antenna board 4, and an end part 62 on the “X2” side is abutted with the control board 7.

### (Control Board)

As shown in FIG. 3, the control board 7 is formed in a flat plate shape. As shown in FIG. 4, the control board 7 is disposed at an end part 62 of the spacer 6. In this state, the control board 7 is not abutted with an end face 352 of the protruded part 35. In other words, the end face 352 of the protruded part 35 is located on the “X1” side with respect to the end part 62 of the spacer 6.

The control board 7 is electrically connected with the antenna board 4 and is provided with a circuit for controlling the antenna board 4. The control board 7 communicates with a medium 2 by electromagnetic induction between the antenna 41 and the medium 2. As shown in FIGS. 2 and 3, the control board 7 includes a connector terminal 71 provided on a face part 72 on the “X2” side and hole parts 73. The connector terminal 71 is protruded through a hole part 38 provided in the second face part 36 to an outer side. The connector terminal 71 is connected with a connector of a host apparatus which is connected with the information processing device 1.

### (Screw)

The screw 5 is made of metal. As shown in FIG. 4, the screw 5 is inserted into the hole part 39 from the “X2” side with respect to the second face part 36 and is fastened to the screw hole 351. In this case, the screw 5 fixes the antenna board 4 to the first case 31 through the bottom face part 370 of the second case 32, the control board 7 and the spacer 6. Further, the spacer 6 presses the antenna board 4 to the support part 34 of the first case 31 by a fastening force of the screw 5 when the screw 5 is fastened to the screw hole 351.

In this embodiment, as shown in FIGS. 3 and 4, the protruded part 35 is provided with a protruded portion 353 which is protruded from the end face 352. An outside diameter dimension of the protruded portion 353 is slightly smaller than a diameter dimension of the hole part 73 of the control board 7. The protruded portion 353 is inserted into the hole part 73 in a state that the protruded portion 353 is not abutted with the bottom face part 370 of the second case 32. As a result, when the antenna board 4, the spacer 6, the control board 7 and the second case 32 are to be attached to the first case 31, the protruded portion 353 functions as a positioning part for the control board 7.

As shown in FIG. 4, when viewed in a direction perpendicular to the “X” direction, the screw 5 is located on the “X2” side with respect to the antenna board 4 and is not overlapped with the antenna board 4. More specifically, when viewed in a direction perpendicular to the “X” direction, the tip end part 53 of the screw 5 is located on the “X2” side with respect to the antenna board 4 and is not overlapped with the antenna board 4.

### Operations and Effects

According to this embodiment, the screw 5 is located on the “X2” side with respect to the antenna board 4 and, when viewed in a direction perpendicular to the “X” direction, the screw 5 is not overlapped with the antenna board 4. As a result, the tip end part 53 of the screw 5 is not located on the “X1” side with respect to the antenna board 4 and thus, influence of the screw 5 can be reduced in communication between a medium 2 and the antenna 41.

The information processing device 1 includes the spacer 6 which is disposed between the antenna board 4 and the head part 51 of the screw 5 in the “X” direction. The case 3 is provided with the support part 34 which supports the antenna board 4 in the “X” direction, and the protruded part 35 which is formed with the screw hole 351 and is protruded to the “X2” side from the first face part 33. The antenna board 4 is provided with the hole part 45 into which the protruded part 35 is inserted. The spacer 6 is formed in a tube shape into which the protruded part 35 is inserted. The spacer 6 presses the antenna board 4 to the support part 34 of the case 3 by a fastening force of the screw 5 when the screw 5 is fastened to the screw hole 351. As a result, even when the screw is located on the “X2” side with respect to the antenna board 4, the screw 5 is capable of fixing the antenna board 4 to the case 3 by using the spacer 6.

The information processing device 1 includes the control board 7 which is disposed at the end part 62 on the “X2” side of the spacer 6 and is provided for controlling the antenna board 4. The screw 5 is fastened to the screw hole 351 through the control board 7. As a result, the antenna board 4 and the control board 7 can be fixed to the case 3 by one screw 5.

The case 3 includes the first case 31 provided with the first face part 33 and the second case 32 which is attached to the first case 31 from the “X2” side and is provided with the second face part 36 provided on the “X2” side. The screw 5 is fastened to the screw hole 351 through the second face part 36 from the “X2” side with respect to the second face part 36. As a result, the antenna board 4, the control board 7 and the second case 32 can be fixed to the first case 31 by one screw.

The antenna 41 is provided on the face 43 on the “X1” side of the antenna board 4. As a result, communication sensibility between a medium 2 and the antenna 41 can be improved.

### Modified Embodiments

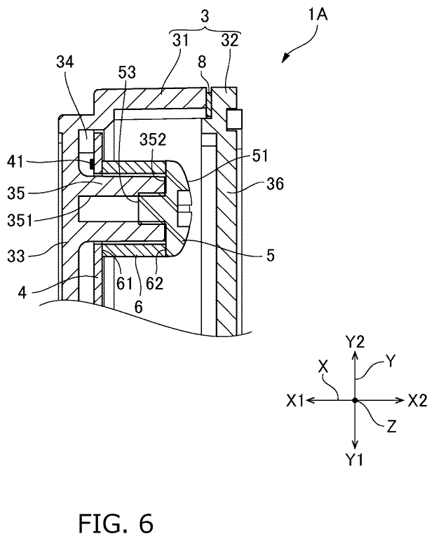

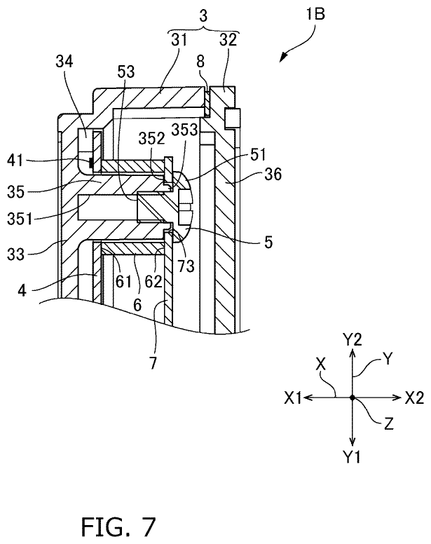

FIG. 6 is a cross-sectional view showing an information processing device in accordance with a first modified embodiment of the present invention. FIG. 7 is a cross-sectional view showing an information processing device in accordance with a second modified embodiment of the present invention. As shown in FIG. 6, in an information processing device 1A in a first modified embodiment of the present invention, the screw 5 may fix the antenna board 4 to the first case 31 by abutting the head part 51 with the end part 62 of the spacer 6. In this case, a washer may be arranged between the head part 51 and the end part 62. As shown in FIG. 7, in an information processing device 1B in a second modified embodiment, the screw 5 may fix the antenna board 4 to the first case 31 by abutting the head part 51 with the control board 7.

Embodiments of the present invention may be structured as follows.

(1) An information processing device communicating with a medium in a non-contact manner including:
a case provided with a first face part to which a medium is brought close;
an antenna board which faces the first face part in an inside of the case and includes an antenna for communicating with the medium; and
a screw made of metal which is fastened to a screw hole formed in the case to fix the antenna board to the case,
where in an arrangement direction in which the first face part and the antenna board are arranged, when a side where the first face part is located is referred to as a first side, and a side where the antenna board is located is referred to as a second side, the screw is located on the second side with respect to the antenna board and, when viewed in a direction perpendicular to the arrangement direction, the screw is not overlapped with the antenna board.

(2) The information processing device described in the above-mentioned structure (1), further including a spacer which is disposed between the antenna board and a head part of the screw in the arrangement direction,
where the case is provided with a support part, which supports the antenna board in the arrangement direction, and a protruded part which is formed with the screw hole and is protruded from the first face part to the second side, the antenna board is provided with a hole part into which the protruded part is inserted, the spacer is formed in a tube shape into which the protruded part is inserted and presses the antenna board to the support part by a fastening force of the screw when the screw is fastened to the screw hole.

(3) The information processing device described in the above-mentioned structure (2), further including a control board for controlling the antenna board which is disposed at an end part on the second side of the spacer, where the screw is fastened to the screw hole through the control board.

(4) The information processing device described in the above-mentioned structure (2) or (3), where the case includes a first case provided with the first face part and a second case which is attached to the first case from the second side and is provided with a second face part provided on the second side, and the screw is fastened to the screw hole through the second face part from the second side with respect to the second face part.

(5) The information processing device described in one of the above-mentioned structures (1) through (4), where the antenna is provided on a face on the first side of the antenna board.

While the description above refers to particular embodiments of the present invention, it will be understood that many modifications may be made without departing from the spirit thereof. The accompanying claims are intended to cover such modifications as would fall within the true scope and spirit of the present invention.

The presently disclosed embodiments are therefore to be considered in all respects as illustrative and not restrictive, the scope of the invention being indicated by the appended claims, rather than the foregoing description, and all changes which come within the meaning and range of equivalency of the claims are therefore intended to be embraced therein.

What is claimed is:

1. An information processing device for performing communication with a medium in a non-contact manner comprising:
a case comprising a first face part to which a medium is brought close;
an antenna board which faces the first face part in an inside of the case and includes an antenna for communicating with the medium; and
a screw made of metal which is fastened to a screw hole formed in the case to fix the antenna board to the case;
wherein, in an arrangement direction in which the first face part and the antenna board are arranged, when a side where the first face part is located is referred to as a first side, and a side where the antenna board is located is referred to as a second side, the screw is located on the second side with respect to the antenna board and, when viewed in a direction perpendicular to the arrangement direction, the screw is not overlapped with the antenna board.

2. The information processing device according to claim 1, further comprising a spacer which is disposed between the antenna board and a head part of the screw in the arrangement direction,
wherein the case comprises a support part, which supports the antenna board in the arrangement direction, and a protruded part which is formed with the screw hole and is protruded from the first face part to the second side,
the antenna board comprises a hole part into which the protruded part is inserted,
the spacer is formed in a tube shape into which the protruded part is inserted and presses the antenna board to the support part by a fastening force of the screw when the screw is fastened to the screw hole.

3. The information processing device according to claim 2, further comprising a control board for controlling the antenna board which is disposed at an end part on the second side of the spacer,
wherein the screw is fastened to the screw hole through the control board.

4. The information processing device according to claim 2, wherein
the case comprises a first case provided with the first face part and a second case which is attached to the first case from the second side and is provided with a second face part provided on the second side, and
the screw is fastened to the screw hole through the second face part from the second side with respect to the second face part.

5. The information processing device according to claim 3, wherein
the case comprises a first case provided with the first face part and a second case which is attached to the first case from the second side and is provided with a second face part provided on the second side, and
the screw is fastened to the screw hole through the second face part from the second side with respect to the second face part.

6. The information processing device according to claim 1, wherein the antenna is provided on a face on the first side of the antenna board.
